(19) United States
(12) Patent Application Publication
(10) Pub. No.: US 2008/0257779 A1
(43) Pub. Date: Oct. 23, 2008

(54) Supporting Member For Thin-Film-Coated Boards, Storage Container For Thin-Film-Coated Boards, Mask-Blank-Storing Body, Transfer-Mask-Storing Body, and Method For Transporting Thin-Film-Coated Boards

(75) Inventor: Akinori Kurikawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION, Shinjuku-ku (JP)

(21) Appl. No.: 11/883,386

(22) PCT Filed: Sep. 29, 2005
(86) PCT No.: PCT/JP05/18001

§ 371 Date: Nov. 13, 2007

(30) Foreign Application Priority Data
Sep. 29, 2004 (JP) 2004-283822

(51) Int. Cl. H01L 21/673; B65D 85/86; A47G 19/08

(52) U.S. Cl. 206/707; 211/41.1; 211/41.17

(57) ABSTRACT

The present invention provides a supporting member for thin-film-coated boards that is capable of sufficiently suppressing dust generated because of particles and the like. The present invention also provides a storage container suitable for storing thin-film-coated boards that has such a supporting member so as to store the thin-film-coated boards at a high level of cleanliness.

The supporting members (2) and (5) have supporting means for supporting the thin-film-coated boards (1) such as mask blanks. The surface of at least a portion of the supporting means that comes into contact with the thin-film-coated boards (1) is permitted to be a smooth plane having an arithmetic average surface roughness (Ra) of 0.1 μm or lower. The surface of at least the portion of the supporting means that comes into contact with the thin-film-coated boards (1) is composed of, for instance, a resin material. The supporting members (2) and (5) are used to support the thin-film-coated boards (1) in the storage container having the supporting members to support the thin-film-coated boards (1) in a fixed state.

### TECHNICAL FIELD

The present invention relates to a supporting member for thin-film-coated boards, such as transfer masks used in production of electronic devices and mask blanks used in production of such transfer masks. The present invention also relates to a storage container having such a supporting member for the thin-film-coated boards, a storing body wherein the mask blanks or the transfer masks are stored in the storage container, and a method for transporting the thin-film-coated boards.

### BACKGROUND ART

Recently, information technology has been advancing rapidly, and thus miniaturization is increasingly being demanded in manufacturing of electronic devices, in particular, semiconductor devices and color filters and TFT devices used in liquid crystal displays. One of the technologies that assist such fine processing is a lithographic technique using a photomask referred to as a transfer mask. In such a lithographic technique, a resist-film-coated silicon wafer is exposed to electromagnetic waves generated by a light source for light exposure through the transfer mask and as a result, the surface of the silicon wafer is fine-patterned. In general, such a transfer mask is produced by forming, using the lithographic technique, an original pattern on a mask blank obtained by coating an opaque film and the like on the surface of a translucent board. However, if any foreign matter such as particles exists on the surface of the mask blank, the resulting pattern may become defective. Therefore, the surface of the mask blank should be stored at a high level of cleanliness so as to avoid any adhesion of foreign matters.

As an example of a container for storing and transporting such mask blanks, the mask-transporting case described in Patent Document 1 below is known.

More specifically, the known container for storing mask blanks has a structure in which a few or dozens of mask blanks are arranged and held in an inner case, often referred to as a carrier, this inner case containing the mask blanks is stored in an outer case (a case body), and then the outer case is covered with a lid. The joints between the outer case and the lid are tightly sealed with an adhesive tape so as to avoid contamination by external air, foreign matter and the like.

Patent Document 1: Japanese Unexamined Patent Application Publication (JP-A) No. 2001-154341

### DISCLOSURE OF INVENTION

### Problems to be Solved by the Invention

Miniaturization of patterns formed on transfer masks is increasingly demanded with recent performance enhancement of electronic devices, and the fine-patterning processes require an extremely high cleanliness of mask blanks. Therefore, adhesion of foreign matter and the like should be as completely avoided as possible to maintain the mask blanks as clean as possible, in particular, during storage.

Known approaches for preventing dust generation during handling and storage of the mask blanks and the like put an emphasis on the cleanliness of a board. Applying a resist film coating on the mask blank results in the resist film being formed not only on the main surface of the mask blank but also on the peripheral end faces thereof, so that one of such approaches removes the peripheral portions of the film unnecessary for patterning the mask to suppress dust generation due to the presence of the resist film. This approach is based on the fact that the resist film portions coated on the end faces of the mask blank are likely to be in contact or rubbed with other members during handling of the mask blank or while the mask blank is taken in and out of the container.

In another approach, the mask blanks and the like are stored in clean atmosphere by using plastics or other materials that are unlikely to emit chemical substances or other foreign matter as material of the storage container for storing thin-film-coated boards such as the mask blanks, as known in the above-mentioned Patent Document 1.

However, the inventor found in their research that none of the known means sufficiently suppresses dust generation. More specifically, the inventor found that although each of the known means actually has some effect on suppression of dust generation, the effect of the individual known means is not sufficient for achieving the extremely high cleanliness required in fine-patterning of the mask blanks for producing high-performance electronic devices today.

Considering the situation described above, the first object of the present invention is to provide a supporting member for a thin-film-coated board that can resolve the abovementioned problems of the known approaches and can sufficiently suppress dust generation due to the presence of particles. The second object of the present invention is to provide a storage container that has such a supporting member so as to store the thin-film-coated board at a high level of cleanliness and thus is suitable for storing the thin-film-coated board, and a storing body where the mask blanks or the transfer masks are stored in such a storage container.

### Means for Solving the Problems

Conventional approaches have been based on the recognition that the main cause of dust generation is the board. However, one of the causes of dust generation seems to be, for example, an instance caused by friction between any two members. The inventor therefore made research from the perspective that the members that are in contact with the board should be examined as well as the board itself.

In general, a storage container for mask blanks and the like has a supporting member, sometimes referred to as a retainer, for supporting the mask blanks and the like in a fixed state so as to avoid any displacement of the mask blanks and the like stored in the container. The inventor examined this supporting member that is to be in direct contact with the thin-film-coated boards such as the mask blanks and found that dust generation is related to the surface roughness of the portion of the supporting member that is to be in contact with the thin-film-coated boards.

These findings prompted the inventor to make further investigations for resolving the abovementioned problems, and the inventor finally completed the present invention stated below.

More specifically, the present invention has the following configurations.

(Configuration 1) A supporting member for thin-film-coated boards, comprising supporting means for supporting the thin-film-coated boards, wherein the surface of at least a portion of the supporting means that is to be in contact with the thin-film-coated boards is smooth plane having an arithmetic average surface roughness (Ra) of 0.1 μm or lower.
(Configuration 2) The supporting member for the thin-film-coated boards according to Configuration 1, wherein the surface of at least a portion of the thin-film-coated boards that is to be in contact with the supporting means is a specular surface.
(Configuration 3) The supporting member for the thin-film-coated boards according to Configuration 1 or 2, wherein each of the thin-film-coated board comprises major surfaces and end faces formed at circumferential edges of the major surface, the end faces include the lateral surfaces of each thin-film-coated board and cut bezels lying between the lateral surfaces and the major surfaces, and each thin-film-coated board is supported by bringing the supporting means in contact with the cut bezels.
(Configuration 4) The supporting member for the thin-film-coated boards according to any one of Configurations 1 to 3, wherein a resin material is used to form the surface of at least the portion of the supporting means that is to be in contact with the thin-film-coated boards.
(Configuration 5) A storage container for thin-film-coated boards comprising a supporting member for supporting the thin-film-coated boards in a fixed state, wherein the thin-film-coated boards are supported by the supporting member according to any one of Configurations 1 to 4.
(Configuration 6) A mask-blank-storing body storing mask blanks each having a surface which should be patterned so as to form a transfer mask, wherein each mask blank having a thin film for mask-patterning on a board is stored in the storage container according to Configuration 5.
(Configuration 7) A transfer-mask-storing body storing transfer masks each having a surface on which a mask pattern has been formed, wherein the transfer mask are stored in the storage container according to Configuration 5.
(Configuration 8) A transportation method for thin-film-coated boards comprising storing the thin-film-coated boards in the storage container according to Configuration 5 and transporting them.

The present invention is described in more details below.

The supporting member for thin-film-coated boards according to the present invention is, as described in Configuration 1, a supporting member comprising supporting means for supporting the thin-film-coated boards. The supporting member is characterized in that the surface of at least a portion of the supporting means that is in contact with the thin-film-coated boards is a smooth plane having an arithmetic average surface roughness (Ra) of 0.1 μm or lower.

Dust generation due to a contact between the thin-film-coated board and the supporting means for supporting the board can be favorably suppressed by forming the surface of at least a portion of the supporting means that is in contact with the thin-film-coated board into a smooth plane.

The thin-film-coated board described herein is, for example, a mask blank obtained by coating a thin film such as an opaque film on the surface of a translucent board such as a glass board. The mask blank is not restricted to a mask blank for a so-called binary mask that is obtained by coating an opaque film (such as a chrome film) on a translucent board. For example, the mask blank used to produce a phase-shift mask is prepared by coating a phase-shift film only or both the phase-shift film and an opaque film on a translucent board. Also, the mask blank used to produce a reflective mask for extreme ultraviolet exposure has both a light-reflecting film and a light-absorbing film on a board.

The thin-film-coated board further may comprise a resist film on the mask blank described above. Although the presence of the resist film would be likely to result in dust generation, the supporting member according to the present invention can suppress dust generation even when the resist film is applied on the thin-film-coated board. The use of the resist film is thus particularly preferable.

In addition, the thin-film-coated board may be a transfer mask obtained by lithographically patterning the thin film coated on the board for masking prepared using one of the mask blanks described above.

In the supporting member according to the present invention, a smooth plane is formed on the surface of at least a portion of the supporting means that is in contact with the thin-film-coated boards, and the arithmetic average surface roughness (Ra) of the smooth plane is equal to or lower than 0.1 μm. In the present invention, the value Ra refers to the arithmetic average surface roughness calculated in accordance with Japanese Industrial Standards (JIS) B0601. The arithmetic average surface roughness (Ra) of the supporting member according to the present invention can be calculated from, for example, a value of the surface profile measured using a contact surface profiler.

Also, as described in Configuration 2, a specular surface is formed on the surface of at least a portion of the thin-film-coated boards that is in contact with the supporting means described above.

Each thin-film-coated board is in a configuration where a thin film is formed on the flat board and thus has two major surfaces of an upper surface and a lower surface, and end faces formed at circumferential edges of the major surfaces, namely, lying between the upper and lower major surfaces. In such a configuration, at least a portion of the thin-film-coated boards that is in contact with the supporting means is usually end faces of the thin-film-coated boards. For example, in a mask blank, the major surfaces of each thin-film-coated board provide an area to be patterned for masking. This area is preferably prevented from being in contact with other members as much as possible during handling and storage of the board. Meanwhile, the end faces of each thin-film-coated board are not involved in patterning for masking and thus can be used for holding the board securely.

The supporting member according to the present invention is suitable for supporting thin-film-coated boards in which a specular surface is formed on the surface of a portion of the thin-film-coated boards that is in contact with the abovementioned supporting means. In general, the end faces of the glass board used as a mask blank board are polished so as to be specular surfaces having an arithmetic average surface roughness (Ra) of 1 nm or lower. In other words, the end faces are quite smooth planes, so that the surfaces of thin films formed on the end faces are also smooth planes. In addition, the definition of the arithmetic average surface roughness (Ra) is the same as described earlier.

Meanwhile, the abovementioned end faces of each thin-film-coated board include the lateral surfaces of the thin-film-coated board and the cut bezels lying between the lateral surfaces and the major surfaces. The supporting member for thin-film-coated boards according to the present invention supports the thin-film-coated boards preferably by bringing the abovementioned supporting means in contact with the cut bezels, as described in Configuration 3. This enables the supporting means to support the thin-film-coated boards securely with a minimum necessary area in contact with the thin-film-coated boards. In addition, in a glass board used as a mask blank substrate, the cut bezels of the end faces are often polished so as to be specular surfaces having an arithmetic average surface roughness (Ra) of 1 nm or lower. The definition of the arithmetic average surface roughness (Ra) is also the same as described earlier.

In the supporting member for thin-film-coated boards according to the present invention, a resin material is preferably used to form the surface of at least a portion of the supporting means that is in contact with the thin-film-coated boards as described in Configuration 4, from a viewpoint of formability, lightweight properties, costs, and so on. In this case, materials other than resin may be used for forming the members except for the surface of at least the portion of the supporting means that is in contact with the thin-film-coated boards, as long as the abovementioned surface is formed using a resin material. Considering formability, lightweight properties, costs, and so on, however, the entire supporting member is preferably formed of a resin material. Preferable examples of the resin material used in the present invention include polybutylene terephthalate (abbreviated to PBT). PBT is harder than other resin materials, and suitable for forming a smooth plane having an arithmetic average surface roughness (Ra) of 0.1 μm or lower as the surface of at least the portion of the supporting means that is in contact with the thin-film-coated boards when processed in a resin molding technique. Of course, PBT is not the only material used to form the supporting member according to the present invention, and a resin material other than PBT may also be used. Furthermore, in the supporting member formed of a resin material, an appropriate surface treatment may also result in formation of a smooth plane having a desired surface roughness on the surface of at least the portion of the supporting means that is in contact with the thin-film-coated boards.

As described in Configuration 5, the storage container for thin-film-coated boards according to the present invention comprises a supporting member for supporting the thin-film-coated boards in a fixed state. This storage container supports the thin-film-coated boards using one of the supporting members described in Configurations 1 to 4 above.

In this storage container comprising the supporting member according to the present invention, dust generation can be favorably suppressed and the thin-film-coated boards can be stored securely.

Any structure may be employed for this storage container as long as the structure accommodates one or more thin-film-coated boards and, more preferably, prevents a direct entry of the external air into the container with the lid of the container closed. Furthermore, no limitation is put on the material used to form the storage container according to the present invention. Considering formability, lightweight properties, costs, and so on, however, the entire supporting member is preferably formed of a resin material. In this case, the resin material may be the same as or different from one used to form the supporting member according to the present invention constituting the storage container.

The resin material used to form the storage container is appropriately selected from resins such as polypropylene, acryl compounds, polyethylene, polycarbonates, polyesters, polyamides, polyimides, polyethylsulfite, and so on.

In addition, the supporting member according to the present invention may be formed using the same material as that used to form the storage container with an integral molding technique, or may be prepared independently of the storage container for the subsequent installation inside the storage container.

With the mask-blank-storing body obtained by storing mask blanks in the abovementioned storage container according to the present invention as described in Configuration 6, dust generation in the storing body can be favorably suppressed, the surface of the mask blanks is protected from adhesion of foreign matter, and thus the mask blanks can be stored at a high level of cleanliness. This configuration is particularly suitable to be used in the mask-blank-storing body having a resist film on the surface of the mask blank.

Also, with the transfer-mask-storing body obtained by storing transfer masks in the abovementioned storage container according to the present invention as described in Configuration 7, dust generation in the storing body can be favorably suppressed, the surface of the transfer masks is protected from adhesion of foreign matter, and thus the transfer masks can be stored at a high level of cleanliness.

Furthermore, any vibration or the like would not promote dust generation inside the storage container in the transportation method described in Configuration 8, in which thin-film-coated boards are stored in the storage container according to the present invention. This ensures secure storage of the thin-film-coated boards and thus realizes the high-security and long-distance transportation of the thin-film-coated board.

Though a mask blank and a transfer mask are mentioned as examples of the thin-film-coated board in the explanation above, the present invention can be applied also to a magnetic-thin-film-coated board, i.e., a disk-shaped substrate coated by a magnetic thin film such as a magnetic disk, and the like.

### EFFECTS OF THE INVENTION

The present invention can provide a supporting member for thin-film-coated boards that sufficiently suppresses dust generation due to particles and the like.

Also, the present invention can provide a storage container suitable for storing thin-film-coated boards. This storage container comprises such a supporting member so as to store the thin-film-coated boards at a high level of cleanliness.

Furthermore, the present invention can provide a storing body in which mask blanks or transfer masks are stored in such a storage container at a high level of cleanliness. Moreover, transporting the thin-film-coated boards stored in the storage container ensures secure storage of the thin-film-coated boards and thus realizes the high-security and long-distance transportation of the thin-film-coated boards.

### BEST MODE FOR CARRYING OUT THE INVENTION

The embodiments of the present invention are described below with reference to the drawings.

FIGS. 1 to 4 individually show an embodiment of a storage container for thin-film-coated boards according to the present invention. FIG. 1 is a perspective view of a lid of the storage container, FIG. 2 is a perspective view of a state where the thin-film-coated boards are stored in an inner case, FIG. 3 is a perspective view of a case body (outer case) of the storage container, and FIG. 4 is a longitudinal sectional view of a state where the thin-film-coated boards are stored in the storage container.

In this embodiment, mask blanks are used as an example of the thin-film-coated boards for explanation. Needless to say, it may be available as a storage container for transfer masks or the like.

The storage container in this embodiment has a structure in which an inner case (a supporting member) 2 stores mask blanks 1 each of which is prepared by coating one of the two square major surfaces of a glass board with an opaque film, such as a chrome film, and subsequently forming a resist film thereon, then the inner case 2 is stored in the case body 3, and finally the opening of the case body 3 is covered with a lid 4 (FIG. 4).

Another structure is also allowed, in which the mask blanks 1 are stored directly in the case body 3 that has grooves or the like without using the abovementioned inner case 2. However, the use of the inner case 2 according to this embodiment enables handling a few or dozens of mask blanks stored in the inner case 2 at one time, and thus is effective.

The inner case 2 according to this embodiment has pairs of grooves (supporting means) 21 and 22 that are formed on a pair of opposite inner surfaces so as to extend from the opening (upper side) to the bottom (lower side) while being arranged with a predetermined interval. The grooves 21 and 22 have windows 23 and 24 on their bottom of the lower side, and the inner case 2 has an opening 27 on its bottom. The inner case 2 also has a board-supporting portion (supporting means) 26 on its bottom, and the board-supporting portion 26 supports the lower end face 13 of the mask blank 1 (FIGS. 2 and 4). Furthermore, the inner case 2 has a pair of concave portions 28 and 29 used for fixing the inner case 2 in the case body 3. The concave portions 28 and 29 are formed on the intact outer surfaces, i.e., the outer side of a pair of opposite walls, so as to extend from the bottom halfway to the opening (FIG. 2). In addition, the height from the upper end face 25 of the inner case 2 opening to the board-supporting portion 26 is substantially equivalent to the height of the mask blanks 1 to be stored. Therefore, the upper part of the mask blanks 1 sticks out slightly higher than the upper end face 25 of the inner case 2 during the mask blanks 1 are stored in the inner case 2 (FIG. 4). When a few mask blanks 1 are inserted along pairs of the grooves 21 and 22 formed inside the inner case 2, the mask blanks 1 stand close together in parallel with each other while being arranged with a predetermined interval. Though in this embodiment the mask blanks 1 stand close together in a vertical direction, they may stand close together in an inclined direction.

The case body 3 according to the present invention has projecting portions 31 and 32 that fit the abovementioned concave portions 28 and 29 of the inner case 2 on a pair of opposite inner surfaces, and the bottom of the projecting portions 31 and 32 are in contact also with the bottom of the case body 3 (FIG. 3). The case body also has convex portions 33 and 34 which are formed on a pair of opposite outer surfaces and positioned near the opening of the case body. Moreover, an outer circumference 36 is formed at a height slightly lower than the opening edge 35 so as to its surface is on the substantially same plane on which the surfaces of the abovementioned convex portions 33 and 34 exist.

The lid 4 according to this embodiment has concave portions 43 and 44 on its engaging pieces 41 and 42 that are extend from a pair of opposite sides of the lower edge 47 (the edge of the opening used to cover the case body; seen at the upper side of the lid shown in FIG. 1). When the lid 4 covers the case body 3, the concave portions 43 and 44 respectively engage with the convex portions 33 and 34 of the case body 3 so as to fix the lid 4 over the case body 3 (FIG. 4). The lid also has stoppers 45 and 46 on a pair of opposite inner surfaces (FIG. 1). These stoppers fix the inner case 2 in the vertical direction by pressing the upper end face 25 of the opening of the inner case 2. In addition, another configuration is allowed, in which the lid 4 is simply put on the case body 3 without using the concave portions 43 and 44 of the lid 4 and the convex portions 33 and 34 of the case body 3.

The material used to form the inner case 2, the case body 3 and the lid 4 described above is appropriately selected from resins such as polypropylene, acryl compounds, polyethylene, polycarbonates, polyesters, polyamides, polyimides and polyethylsulfite, with polycarbonates and polyesters being preferable. The case body 3 and the lid 4 are preferably made of polycarbonate, whereas the inner case 2 is preferably made of polyester. However, the inner case 2 according to the present invention may be made of PBT from the viewpoint that PBT facilitates the resin molding process to obtain a smooth plane of 0.1 μm or lower as described earlier. Polyethylene oxide (PEO) may also be used as a resin material of the inner case 2 and a retainer 5 described later.

In some cases, charges accumulated in a mask blank during storage thereof may cause discharge breakdown to occur in the manufacturing process of the mask and result in defects in patterning. A considered preferable approach to resolve this problem is the addition of carbons or other materials to the resin material of the case body 3 so that the case body has conductivity.

The retainer (supporting member) 5 according to the present invention includes, as shown in FIG. 5, a straight shaft 51 having a circular section, several pairs of connections 52 and 53 projecting from the shaft 51 so as to intersect with each other at right angle on the section of the shaft, and several pairs of contact portions 54 and 55 that are formed at the end of the connections 52 and 53 so as to have a circular section. The several pairs of connections 52 and 53 and contact portions 54 and 55 are arranged with an interval that is equivalent to the predetermined interval lying between each of the grooves 21 and 22 of the inner case 2. Furthermore, the contact portions 54 and 55 have contact surfaces (supporting means) 56 and 57 intersecting with each other at right angle.

Two pieces of such a retainer 5 are respectively inserted along shaft holders 6 and 7 installed inside the lid 4 (FIG. 4). These shaft holders 6 and 7 are installed on opposite inner surfaces of the lid so as to face each other, and hold the shaft 51 of the retainer 5 so that the shaft 51 can freely rotate around the axis thereof.

After the lid 4 covers the case body 3 containing the inner case 2 in which several mask blanks 1 have been stored, the contact surfaces 56 and 57 of the contact portions 54 and 55 of the retainer 5 are respectively brought to be in contact with the upper end face 11 and the lateral end faces 12 of the mask blanks 1 at the upper corners thereof so as to fix the mask blanks 1. Among resin materials, PBT is preferable as a material of the retainer 5 considering the fact that PBT facilitates the resin molding process to obtain a smooth plane of 0.1 μm or lower. The contact surfaces 56 and 57 are formed so that the sides to be in contact with the end faces of the mask blanks 1 are smooth planes having Ra of 0.1 μm or lower.

In this embodiment, the lower end faces 13 of the mask blanks 1 are supported by the board-supporting portion 26 formed on the bottom of the inner case 2, as described earlier. This board-supporting portion 26 is also formed so that its surface to be in contact with the end faces of the mask blanks 1 is a smooth plane having Ra of 0.1 μm or lower.

Furthermore, in this embodiment, the lateral end faces 12 of the mask blanks 1 are supported by the grooves 21 and 22 formed so as to extend from the opening (upper side) to the bottom (lower side) of the inner case 2, as described earlier. These grooves 21 and 22 are also formed so that their surfaces to be in contact with the end faces of the mask blanks 1 are smooth planes having Ra of 0.1 μm or lower.

As is in this embodiment, Ra is preferably 0.1 μm or lower for all of the contact surfaces 56 and 57 of the retainer 5, the surface of the board-supporting portion 26, and the surfaces of the grooves 21 and 22 so that these surfaces are smooth. However, another embodiment is also allowed, in which only any one or two of these surfaces is such a smooth plane.

FIG. 6 is an elevational view, partially broken away, showing another embodiment of the storage container for thin-film-coated boards according to the present invention.

The storage container 100 according to this embodiment comprises a case body (an outer case) 101, an inner case (a supporting member) 102 that is installed within the case body 101, and a lid 103 covering the case body 101. The case body 101 has a flanged fitting portion 101a around its opening on the top, and the fitting portion 101a engages with another fitting portion 103a formed around the lid 103. The two fitting portions are latched to each other by another member, a hook 104, so that the case body 101 and the lid 103 are integrally fixed. Furthermore, the case body 101 has feet 101b on one side of its outer surface. Therefore, the storage container 100 can stand with stability even when the storage container 100 according to this embodiment in the state shown in FIG. 1 is overturned so as to stand on the feet 101b (i.e., horizontally placed). In this state, the mask blanks 1 are in a horizontal attitude and thus can load and unload the boards by a robot.

Also, the lid 103 has a retainer (a supporting member) 105 on its backside. Therefore, covering the case body 101 with the lid 103 results in the contact between the contact surface (supporting means) 105a of the retainer 105 and the upper corners of the mask blanks 1 (cut bezels), and thus the mask blanks 1 are supported in a fixed state. This retainer 105 is made of, for example, PBT. The contact surface 105a in contact with the ends of the mask blanks 1 is a smooth plane having Ra of 0.1 μm or lower.

Furthermore, the inner case 102 has board-supporting grooves (supporting means) 102b on its inner wall, and has supporting pieces (supporting means) 102a that support the lower end of the boards on its bottom. Also as for these board-supporting grooves 102b and supporting pieces 102a, the surface of the portions to be in contact with the ends of the mask blanks 1 is a smooth plane having Ra of 0.1 μm or lower. Ra is preferably 0.1 μm or lower for all of the contact surfaces 105a of the retainer 105, the surface of the board-supporting grooves 102b, and the surface of the supporting pieces 102a so that these surfaces are smooth. However, another embodiment is also allowed, in which only any one or two of these surfaces is/are such a smooth plane.

Specific examples are described below. Though the following description mentions the examples using the storage container 100 shown in FIG. 6, the storage container 10 described earlier and shown in FIGS. 1 to 5 has a similar effect to that thereof.

### EXAMPLES

Resist-film-coated mask blanks 1 were prepared by forming a half-tone film and an opaque film on a quartz board (6 inches×6 inches) using a sputtering technique and subsequently forming a resist film thereon using a spin-coating technique. In this step, a MoSi-type metal film was used as the half-tone film, a Cr metal film was used as the opaque film, and a positive-type, chemically-amplified resist film was used as the resist film.

The thus-prepared mask blanks 1 were stored in the storage containers 100 in the abovementioned embodiment shown in FIG. 6. The mask blanks 1 were separately stored in three storage containers (Examples 1, 2 and 3) of which the lid 103 and the main case 101 had been made of polycarbonate, the inner case 102 had been made of PBT, and the retainer 105 had been made of PBT, and in another storage container (Comparative Example 1) in which polyethylene was used to form the retainer 105 instead of PBT. This storing working was performed in a clean room.

Each of the abovementioned storage containers was evaluated for the surface roughness of the portion of the retainer 105 that was in contact with the end faces of the mask blanks 1 using FormTalysurf S4F, a contact surface profiler manufactured by Taylor Hopson, Ltd. The measured Ra was 0.05 μm in Example 1, 0.05 μm in Example 2, 0.10 μm in Example 3, and 0.13 μm in Comparative Example 1. The surface roughness Ra of the inner case 2 in Comparative Example 1 was 0.13 μm. In addition, the end faces of the mask blanks produced had been polished so as to be specular surfaces, and the surface roughness Ra thereof was 0.5 nm when measured using an atomic force microscope (AFM).

The storage containers (mask-blank-storing bodies) that respectively contained these mask blanks were tested for their vibration resistance. This vibration test was conducted according to Military Specifications and Military Standards MIL-STD-810D. This test simulated the vibration conditions in general automobiles.

After the vibration test, the storage containers were opened in the clean room described earlier. The mask blanks were taken out of the storage containers and then evaluated for the number of defects due to adhesion of foreign matter on the major surfaces using a defect detector. In this test, evaluation was made based on the increase in the number of defects detected after the vibration test from the value obtained before the vibration test. As a result, no increase in the number of defects was observed in any of the storage containers of Examples 1, 2 and 3, whereas the increment was 4 in the storage containers of Comparative Example 1. Furthermore, in Comparative Example 1, PBT resin spots were observed on the cut bezels of the mask blanks that were in contact with the retainer 105 and the inner case 102, whereas no such resin spot was observed in the examples.

In the storage container of Comparative Example 2, PBT was used as the material of the inner case 102 and the retainer 105, and the surface roughness Ra of the inner case 102 and the retainer 105 was 0.13 μm. The mask blanks 1 were stored in this storage container and the obtained increment of the number of defects was 6.

Furthermore, in the storage container of Example 4, polyethylene was used as the material of the inner case 102 and the retainer 105, and the surface roughness Ra of the retainer 105 was 0.10 μm. The mask blanks 1 were stored in this storage container and the same vibration test as that performed in the examples described above. The test resulted in the increment of the number of defects being zero.

Moreover, in the storage container of Example 5, PBT was used as the material of the inner case 102 and the retainer 105, and the surface roughness Ra of the inner case 102 and the retainer 105 was 0.05 μm. The mask blanks 1 were stored in this storage container and the same vibration test as that performed in the examples described above. The test resulted in the increment of the number of defects being zero.

In the storage container of Example 6, PBT was used as the material of the inner case 102 and the retainer 105, and the surface roughness Ra of the retainer 105 and the inner case 102 was 0.05 μm and 0.10 μm, respectively. The mask blanks 1 were stored in this storage container and the same vibration test as that performed in the examples described above. The test resulted in the increment of the number of defects being zero.

Also, in the storage container of Example 7, PBT was used as the material of the inner case 102 and the retainer 105, and the surface roughness Ra of the retainer 105 and the inner case 102 was 0.05 μm and 0.13 μm, respectively. The mask blanks 1 were stored in this storage container and the same vibration test as that performed in the examples described above. The test resulted in the increment of the number of defects being zero.

In addition, the surface roughness of the inner case 102 and the retainer 105 can be modified by changing the surface roughness of the die used to molding the inner case 102 and the retainer 105.

### BRIEF DESCRIPTION OF THE DRAWINGS

FIG. 1 is a perspective view of the lid of the storage container.

FIG. 2 is a perspective view of a state where the mask blanks are stored in the inner case.

FIG. 3 is a perspective view of the case body (outer case) of the storage container.

FIG. 4 is a longitudinal sectional view of a state where the mask blanks are stored in the storage container.

FIG. 5 is a perspective view of the supporting member.

FIG. 6 is an elevational view, partially broken away, showing another embodiment of the storage container according to the present invention.

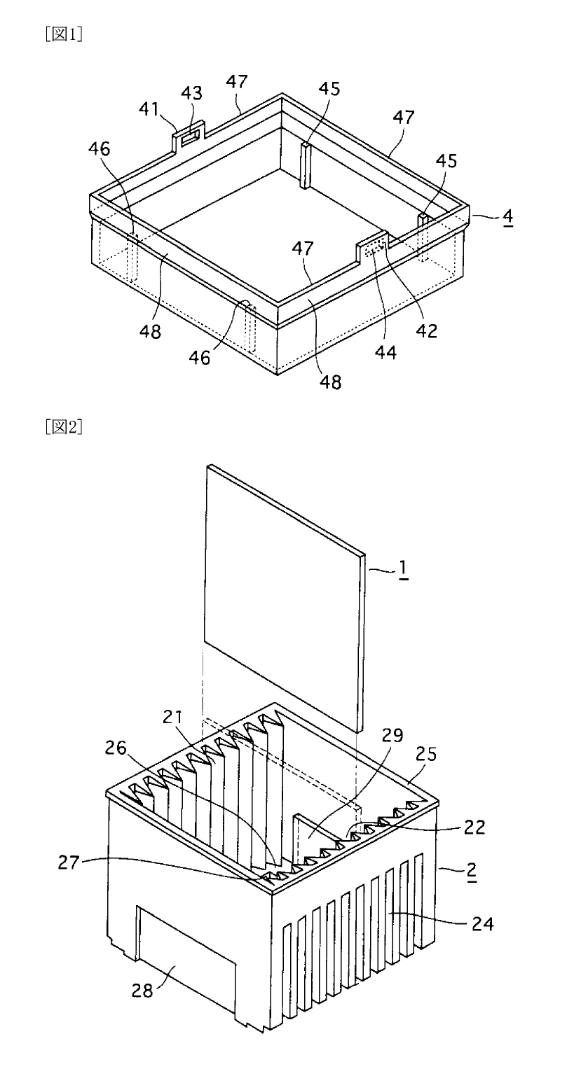

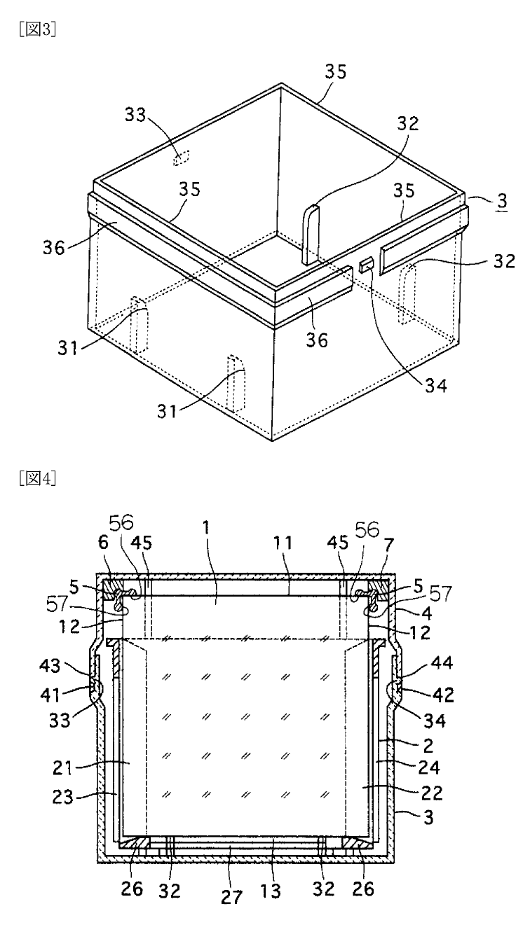

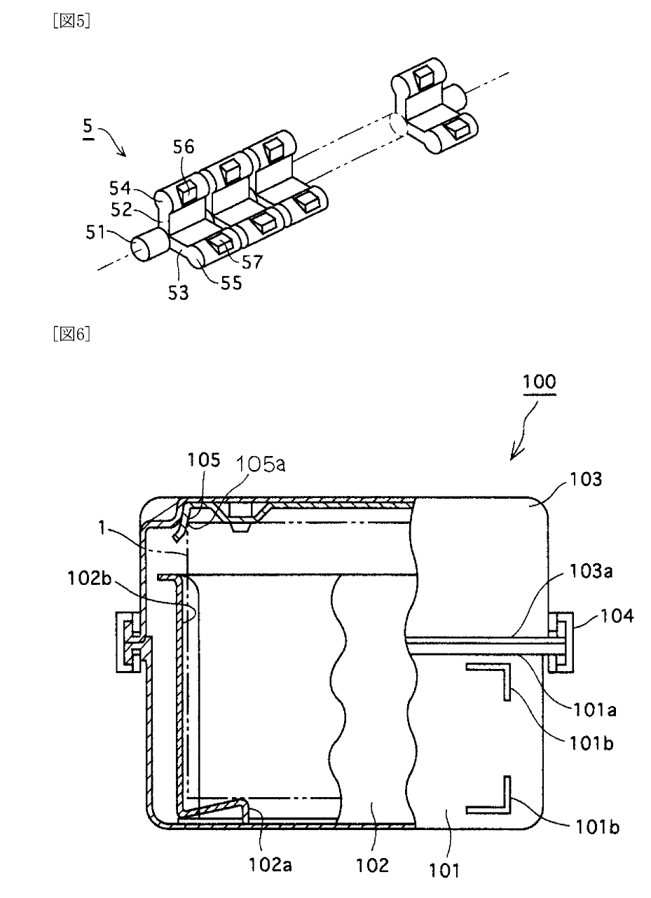

### REFERENCE NUMERALS

1 Mask blank (thin-film-coated board)
2 Inner case (supporting member)
3 Case body
4 Lid
5 Retainer (supporting member)
6, 7 Shaft holder
11 Upper end face
12 Lateral end face
13 Lower end face
21, 22 Groove (supporting means)
23, 24 Window
25 Upper end face
26 Board-supporting portion (supporting means)
27 Opening
28, 29 Concave portion
31, 32 Projecting portion
33, 34 Convex portion
35 Opening outer edge
36 Outer circumference
41, 42 Engaging piece
43, 44 Concave portion
45, 46 Stopper
47 Lower edge
51 Shaft
52, 53 Connection portion
54, 55 Contact portion
56, 57 Contact surface (supporting means)
100 Storage container
101 Case body (outer case)
101a Fitting portion
101b Foot
102 Inner case (supporting member)
102a Supporting piece (supporting means)
102b Board-supporting groove (supporting means)
103 Lid
104 Hook
105 Retainer (supporting member)
105a Contact surface (supporting means)

1. A supporting member for thin-film-coated boards, comprising supporting means for supporting the thin-film-coated boards, wherein the surface of at least a portion of the supporting means that is to be in contact with the thin-film-coated boards is a smooth plane having an arithmetic average surface roughness (Ra) of 0.1 μm or lower.

2. The supporting member for the thin-film-coated boards according to claim 1, wherein the surface of at least a portion of the thin-film-coated boards that is to be in contact with the supporting means is a specular surface.

3. The supporting member for the thin-film-coated boards according to claim 1, wherein each of the thin-film-coated boards comprises major surfaces and end faces formed at circumferential edges of the major surfaces, the end faces include the lateral surfaces of the thin-film-coated boards and cut bezels lying between the lateral surfaces and the major surfaces, and each thin-film-coated board is supported by bringing the supporting means in contact with the cut bezels.

4. The supporting member for the thin-film-coated boards according to claim 1, wherein a resin material is used to form the surface of at least the portion of the supporting means that is to be in contact with the thin-film-coated boards.

5. A storage container for thin-film-coated boards comprising a supporting member for supporting the thin-film-coated boards in a fixed state, wherein the thin-film-coated boards are supported by the supporting member according to claim 1.

6. A mask-blank-storing body storing mask blanks each having a surface which should be patterned so as to form a transfer mask, wherein each mask blank having a thin film for mask-patterning on a board is stored in the storage container according to claim 5.

7. A transfer-mask-storing body storing transfer masks each having a surface on which a mask pattern has been formed, wherein the transfer masks are stored in the storage container according to claim 5.

8. A transportation method for thin-film-coated boards comprising storing the thin-film-coated boards in the storage container according to claim 5 and transporting them.
